(19) United States
(12) Patent Application Publication
(10) Pub. No.: US 2020/0208051 A1
(43) Pub. Date: Jul. 2, 2020

(54) COMPOSITION FOR SEMICONDUCTOR SURFACE TREATMENT AND TREATMENT METHOD OF SEMICONDUCTOR SURFACE

(71) Applicant: JSR CORPORATION, Tokyo (JP)

(72) Inventors: Kiyotaka Mitsumoto, Tokyo (JP); Keisuke Sato, Tokyo (JP); Kiyonobu Kubota, Tokyo (JP)

(73) Assignee: JSR CORPORATION, Tokyo (JP)

(21) Appl. No.: 16/726,907

(22) Filed: Dec. 25, 2019

(30) Foreign Application Priority Data
Dec. 26, 2018 (JP) 2018-242423

(51) Int. Cl. C09K 13/00; H01L 21/3213

(52) U.S. Cl. CPC C09K 13/00; H01L 21/32134

(57) ABSTRACT

Provided are a composition for semiconductor surface treatment capable of effectively diminishing or removing contaminations from a semiconductor surface and suppressing damage to a metal wiring material and the like when being used in treatments such as polishing and cleaning and a treatment method of a semiconductor surface using the composition. The composition for semiconductor surface treatment according to an embodiment of the disclosure contains (A) a compound represented by the following Formula (1) and (B) a compound represented by the following Formula (2):

R¹—L¹—R² (1)

(in Formula (1), R¹ represents a linear or branched alkyl group having 6 to 18 carbon atoms, R² represents an organic group having 2 or more and 5 or less nitrogen atoms, and L¹ represents a single bond or a divalent linking group)

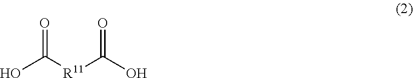

(in Formula (2), R¹¹ represents an organic group having 1 to 12 carbon atoms).

### CROSS-REFERENCE TO RELATED APPLICATIONS

This application claims the priority benefit of Japanese Patent Application No. 2018-242423, filed on Dec. 26, 2018. The entirety of the above-mentioned patent application is hereby incorporated by reference herein and made a part of this specification.

### BACKGROUND OF THE DISCLOSURE

### Technical Field

The disclosure relates to a composition for semiconductor surface treatment and a treatment method of a semiconductor surface using the same.

### Related Art

Chemical mechanical polishing (CMP) has been widely used in the planarization technology in the manufacture of semiconductor devices. The slurry for chemical mechanical polishing used in CMP contains an etching agent and the like in addition to grinding particles (abrasive grains). Moreover, in the manufacture of semiconductor devices, it is required to remove contaminations such as polishing scraps and organic residues from the surface of the semiconductor substrate after CMP, and cleaning of the semiconductor after CMP is an indispensable process that cannot be avoided.

Metal wiring materials such as tungsten and cobalt are exposed on the surface of a semiconductor substrate, and thus CMP and subsequent cleaning are required to be performed in a manner that such a surface to be polished on which the metal wiring materials are exposed is not damaged by corrosion and the like. As a technology to suppress such damage to the surface to be polished, for example, the use of a composition for chemical mechanical polishing in which polyethyleneimine is blended (patent literature 1: Japanese Laid-open No. 2016-524324) and the use of a composition for semiconductor substrate cleaning in which alkanolamine is blended (patent literature 2: Japanese Laid-open No. 2016-171294) have been proposed.

In order to effectively remove polishing scraps and organic residues present on the metal wiring material such as tungsten and cobalt, it is effective to control the surface states between the metal wiring material and the polishing scraps, organic residues, and the like. In order to control the surface states, it is a simple approach to adjust the pH of the composition for semiconductor substrate cleaning to be high.

However, even when the pH of the composition for semiconductor substrate cleaning is adjusted to be high, it is difficult to suppress damage to the metal wiring material and the like only by the addition of polyethyleneimine or alkanolamine.

### SUMMARY

Some aspects according to the disclosure provide a composition for semiconductor surface treatment capable of effectively diminishing or removing contaminations from the semiconductor surface and suppressing damage to a metal wiring material and the like when being used in treatments such as polishing and cleaning and provide a treatment method of a semiconductor surface using the composition.

The disclosure may be realized in the form of any of the following aspects.

An aspect of the composition for semiconductor surface treatment according to the disclosure contains:

(A) a compound represented by the following Formula (1); and

(B) a compound represented by the following Formula (2).

R¹—L¹—R² (1)

(in Formula (1), R¹ represents a linear or branched alkyl group having 6 to 18 carbon atoms, R² represents an organic group having 2 or more and 5 or less nitrogen atoms, and L¹ represents a single bond or a divalent linking group).

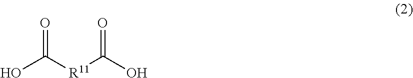

(in Formula (2), R¹¹ represents an organic group having 1 to 12 carbon atoms).

An aspect of the treatment method of a semiconductor surface of the disclosure includes:

a first step of dissolving or dispersing a compound represented by the following Formula (2) in water, an organic solvent, or a mixed solvent of water and an organic solvent;

a second step of further dissolving or dispersing a compound represented by the following Formula (1) in the solution or dispersion after the first step; and

a third step of treating a semiconductor surface using the solution or dispersion after the second step:

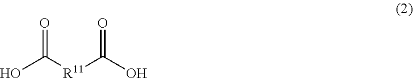

(in Formula (2), R¹¹ represents an organic group having 1 to 12 carbon atoms);

R¹—L¹—R² (1)

(in Formula (1), R¹ represents a linear or branched alkyl group having 6 to 18 carbon atoms, R² represents an organic group having 2 or more and 5 or less nitrogen atoms, and L¹ represents a single bond or a divalent linking group).

### DESCRIPTION OF THE EMBODIMENTS

Hereinafter, embodiments of the disclosure will be described in detail. Moreover, the disclosure is not limited to the following embodiments and also include various modifications implemented in the range in which the spirit of the disclosure is not changed.

An aspect of the composition for semiconductor surface treatment according to the disclosure contains:

(A) a compound represented by the following Formula (1); and

(B) a compound represented by the following Formula (2).

R¹—L¹—R² (1)

(in Formula (1), R¹ represents a linear or branched alkyl group having 6 to 18 carbon atoms, R² represents an organic group having 2 or more and 5 or less nitrogen atoms, and L¹ represents a single bond or a divalent linking group).

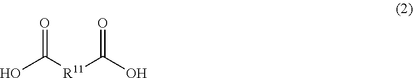

(in Formula (2), R¹¹ represents an organic group having 1 to 12 carbon atoms).

In an aspect of the composition for semiconductor surface treatment, R² in the compound represented by Formula (1) may be a group represented by the following Formula (3).

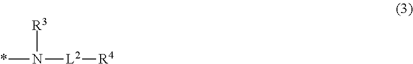

(in Formula (3), R³ represents a hydrogen atom or an aminoalkyl group, R⁴ represents an organic group having 1 to 6 carbon atoms, L² represents a divalent linking group, and * represents a binding site with L¹).

In an aspect of the composition for semiconductor surface treatment, the group represented by Formula (3) may be a group represented by the following Formula (4) or a group represented by the following Formula (5):

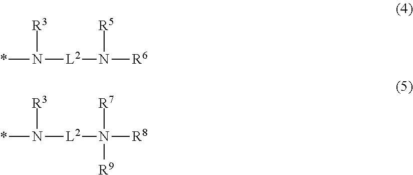

(in Formula (4) and Formula (5), R³ represents a hydrogen atom or an aminoalkyl group, R⁵ and R⁶ in Formula (4) each independently represent a hydrogen atom, an aminoalkyl group, or a carboxyalkyl group, R⁷, R⁸, and R⁹ in Formula (5) each independently represent a linear or branched alkyl group having 1 to 5 carbon atoms or a group represented by the following Formula (6), but at least one of R⁷, R⁸, and R⁹ is a group represented by the following Formula (6), L² represents a divalent linking group, and * represents a binding site with L¹):

*—R¹⁰—COO⁻ (6)

(in Formula (6), R¹⁰ represents an alkylene group having 1 to 3 carbon atoms, and * represents a binding site with N⁺).

In an aspect of the composition for semiconductor surface treatment, R³ in Formula (3) may be an aminoalkyl group having 1 to 6 carbon atoms.

In an aspect of the composition for semiconductor surface treatment, L² in Formula (3) may be a linking group containing at least one selected from the group consisting of alkylene groups having 1 to 5 carbon atoms and an amino group.

In an aspect of the composition for semiconductor surface treatment, L² in Formula (3) may be a linking group containing an alkylene group having 1 to 5 carbon atoms and an amino group.

In any aspect of the composition for semiconductor surface treatment, the compound represented by Formula (1) may be a compound having 3 or more and 5 or less nitrogen atoms.

In any aspect of the composition for semiconductor surface treatment, the compound represented by Formula (2) may be at least one compound selected from the group consisting of citric acid, malonic acid, maleic acid, tartaric acid, malic acid, and succinic acid.

In any aspect of the composition for semiconductor surface treatment, the pH may be 8 or more and 13 or less.

In any aspect of the composition for semiconductor surface treatment, the composition may further contain (C) a water-soluble polymer.

In any aspect of the composition for semiconductor surface treatment, the composition may further contain (D) an organic solvent.

In any aspect of the composition for semiconductor surface treatment, the composition may further contain (E) hydroxylamine.

The composition for semiconductor surface treatment of any aspect may be used for a wiring board.

An aspect of the treatment method of a semiconductor surface of the disclosure includes:

a first step of dissolving or dispersing a compound represented by the following Formula (2) in water, an organic solvent, or a mixed solvent of water and an organic solvent;

a second step of further dissolving or dispersing a compound represented by the following Formula (1) in the solution or dispersion after the first step; and

a third step of treating a semiconductor surface using the solution or dispersion after the second step:

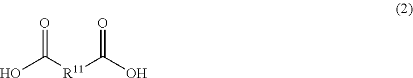

(in Formula (2), R¹¹ represents an organic group having 1 to 12 carbon atoms);

R¹—L¹—R² (1)

(in Formula (1), R¹ represents a linear or branched alkyl group having 6 to 18 carbon atoms, R² represents an organic group having 2 or more and 5 or less nitrogen atoms, and L¹ represents a single bond or a divalent linking group).

### 1. COMPOSITION FOR SEMICONDUCTOR SURFACE TREATMENT

The composition for semiconductor surface treatment according to an embodiment of the disclosure contains (A) a compound represented by the following Formula (1) (hereinafter also referred to as “component (A)”) and (B) a compound represented by the following Formula (2) (hereinafter also referred to as “component (B)”).

R¹—L¹—R² (1)

(In Formula (1), R¹ represents a linear or branched alkyl group having 6 to 18 carbon atoms, R² represents an organic group having 2 or more and 5 or less nitrogen atoms, and L¹ represents a single bond or a divalent linking group.)

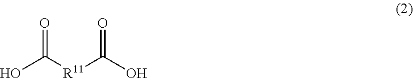

(In Formula (2), R¹¹ represents an organic group having 1 to 12 carbon atoms.)

The composition for semiconductor surface treatment according to the present embodiment can be diluted with an aqueous medium such as pure water if necessary and be used mainly as a cleaning agent to remove particles, metal impurities and the like present on the surface of a semiconductor after CMP. Hereinafter, the respective components contained in the composition for semiconductor surface treatment according to the present embodiment will be described in detail.

### 1.1. Component (A)

The composition for semiconductor surface treatment according to the present embodiment contains (A) a compound represented by the following Formula (1).

R¹—L¹—R² (1)

In Formula (1), R¹ is a linear or branched alkyl group having 6 to 18 carbon atoms, a linear or branched alkyl group having 10 to 18 carbon atoms, or a linear alkyl group having 10 to 18 carbon atoms. By having such an alkyl group, it is possible to effectively diminish or remove contaminations and to suppress corrosion of metals of the metal wiring material and the like.

Specific examples of the linear alkyl group as R¹ include n-hexyl group, n-heptyl group, n-octyl group, n-ethylhexyl group, n-nonyl group, n-decyl group, n-undecyl group, n-dodecyl group, n-tridecyl group, n-tetradecyl group, n-pentadecyl group, n-hexadecyl group, n-heptadecyl group, and n-octadecyl group.

Specific examples of the branched alkyl group as R¹ include methylpentyl group, methylhexyl group, methylheptyl group, methyloctyl group, methylnonyl group, methyldecyl group, methylundecyl group, methyldodecyl group, methyltridecyl group, methyltetradecyl group, methylpentadecyl group, methylhexadecyl group, and methylheptadecyl group; dimethylbutyl group, dimethylpentyl group, dimethylhexyl group, dimethylheptyl group, dimethyloctyl group, dimethylnonyl group, dimethyldecyl group, dimethylundecyl group, dimethyldodecyl group, dimethyltridecyl group, dimethyltetradecyl group, dimethylpentadecyl group, and dimethylhexadecyl group; trimethylbutyl group, trimethylpentyl group, trimethylhexyl group, trimethylheptyl group, trimethyloctyl group, trimethylnonyl group, trimethyldecyl group, trimethylundecyl group, trimethyldodecyl group, trimethyltridecyl group, trimethyltetradecyl group, and trimethylpentadecyl group; ethylbutyl group, ethylpentyl group, ethylhexyl group, ethylheptyl group, ethyloctyl group, ethylnonyl group, ethyldecyl group, ethylundecyl group, ethyldodecyl group, ethyltridecyl group, ethyltetradecyl group, ethylpentadecyl group, and ethylhexadecyl group; propylbutyl group, propylpentyl group, propylhexyl group, propylheptyl group, propyloctyl group, propylnonyl group, propyldecyl group, propylundecyl group, propyldodecyl group, propyltridecyl group, propyltetradecyl group, and propylpentadecyl group; butylpentyl group, butylhexyl group, butylheptyl group, butyloctyl group, butylnonyl group, butyldecyl group, butylundecyl group, butyldodecyl group, butyltridecyl group, and butyltetradecyl group. Moreover, the position of branching is arbitrary in the examples of branched alkyl group.

In Formula (1), L¹ is a single bond or a divalent linking group. Examples of such a divalent linking group include —O—, —S—, —CO—, —CS—, —NR′-(R′ represents a hydrogen atom or a monovalent organic group), a divalent hydrocarbon group, a divalent group obtained by combining these groups, and the like. In particular, a divalent linking group containing at least one selected from the group consisting of alkylene groups having 1 to 5 carbon atoms and —CO— may be used.

In Formula (1), R² is an organic group having 2 or more and 5 or less nitrogen atoms, or an organic group represented by the following Formula (3).

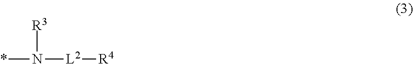

In Formula (3), L² is a divalent linking group. Examples of such a divalent linking group include —O—, —S—, —CO—, —CS—, —NR′-(R′ represents a hydrogen atom or a monovalent organic group), a divalent hydrocarbon group, a divalent group obtained by combining these groups, and the like. In particular, a divalent linking group containing at least one selected from the group consisting of alkylene groups having 1 to 5 carbon atoms and an amino group may be used, and a divalent linking group containing an alkylene group having 1 to 5 carbon atoms and an amino group may be specifically used. Moreover, * in Formula (3) represents a binding site with L¹.

In Formula (3), R³ is a hydrogen atom or an aminoalkyl group and is exemplarily an aminoalkyl group. In addition, when R³ is an aminoalkyl group, and the aminoalkyl group may have 1 to 6 carbon atoms.

In Formula (3), R⁴ is an organic group having 1 to 6 carbon atoms, an organic group having 1 to 6 carbon atoms having at least one selected from the group consisting of a nitrogen atom and N⁺, or an organic group represented by the following Formula (4) or the following Formula (5).

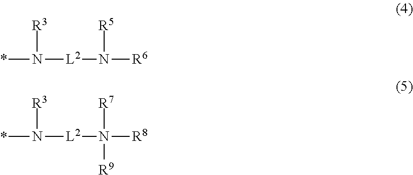

In Formula (4) and Formula (5), R³ is a hydrogen atom or an aminoalkyl group and is exemplarily an aminoalkyl group. In addition, when R³ is an aminoalkyl group, and the aminoalkyl group may have 1 to 6 carbon atoms. In addition, * in Formula (4) and Formula (5) represents a binding site with L¹.

In Formula (4), R⁵ and R⁶ are each independently a hydrogen atom, an aminoalkyl group, or a carboxyalkyl group. When either of R⁵ or R⁶ is an aminoalkyl group, the aminoalkyl group may have 1 to 6 carbon atoms. Moreover, when either of R⁵ or R⁶ is a carboxyalkyl group, the carboxyalkyl group may have 1 to 6 carbon atoms.

In Formula (5), R⁷, R⁸, and R⁹ are each independently a linear or branched alkyl group having 1 to 5 carbon atoms or a group represented by the following Formula (6). However, at least one of R⁷, R⁸, and R⁹ is a group represented by the following Formula (6).

*—R¹⁰—COO⁻ (6)

In Formula (6), R¹⁰ is an alkylene group having 1 to 3 carbon atoms. In addition, * represents a binding site with N⁺.

In Formula (5), when any of R⁷, R⁸, and R⁹ is a linear or branched alkyl group having 1 to 5 carbon atoms, the alkyl group may be a linear alkyl group having 1 to 5 carbon atoms. Moreover, in Formula (5), when any of R⁷, R⁸, and R⁹ is a group represented by Formula (6), R¹⁰ may be an alkylene group having 1 to 2 carbon atoms.

R² in Formula (1) has 2 or more and 5 or less nitrogen atoms, but R² exemplarily has 3 or more and 5 or less nitrogen atoms. By the number of nitrogen atoms in R² being in the above range, the component (A) is likely to protect the metal surface and the like even in a relatively high pH region, and as a result, it is possible to effectively diminish or remove contaminations and to suppress corrosion of metals of the metal wiring material and the like.

Examples of the component (A) in which R² in Formula (1) has 3 or more and 5 or less nitrogen atoms include the component (A) in which at least one of R³, R⁵, and R⁶ in Formula (4) is an aminoalkyl group. In particular, the component (A) in which R³ is an aminoalkyl group and R⁵ and R⁶ are hydrogen atoms or aminoalkyl groups may be used, and the component (A) in which R³ is an aminoalkyl group and R⁵ and R⁶ are hydrogen atoms may be specifically used.

The lower limit value of the content of the component (A) is 0.0001% by mass, 0.001% by mass, or particularly 0.005% by mass with respect to the total mass of the composition for semiconductor surface treatment. A sufficient effect of suppressing corrosion of the metal wiring material and the like may be obtained when the content of the component (A) is equal to or more than the lower limit value. On the other hand, the upper limit value of the content of the component (A) is 1% by mass, 0.1% by mass, or particularly 0.04% by mass with respect to the total mass of the composition for semiconductor surface treatment. Sufficient diminishment or removal of contaminations can be realized when the content of the component (A) is equal to or less than the upper limit value.

### 1.2. Component(B)

The composition for semiconductor surface treatment according to the present embodiment contains (B) a compound represented by the following Formula (2).

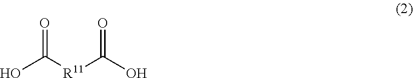

In Formula (2), R¹¹ is not particularly limited as long as it is an organic group having 1 to 12 carbon atoms, but R¹¹ may be an organic group having 1 to 8 carbon atoms and exemplarily an organic group having 1 to 6 carbon atoms. Moreover, R¹¹ may have an amino group (including a secondary amino group and a tertiary amino group), a hydroxy group, a carboxy group, and the like in the structure.

As represented by Formula (2), the component (B) has a carboxy group at both ends of the organic group having 1 to 12 carbon atoms represented by R¹¹. The component (B) having such a structure exhibits high coordination ability with respect to ions composed of semiconductor material elements, and thus contaminations can be effectively diminished or removed.

Specific examples of the component (B) include citric acid, malonic acid, maleic acid, tartaric acid, malic acid, succinic acid, phthalic acid, glutamic acid, aspartic acid, ethylenediaminetetraacetic acid, diethylenetriaminepentaacetic acid, iminodiacetic acid, and the like. In particular, the component (B) may be at least one selected from the group consisting of citric acid, malonic acid, maleic acid, tartaric acid, malic acid, and succinic acid, at least one selected from the group consisting of citric acid and malic acid, or particularly citric acid. If the component (B) is such a component, contaminations can be particularly diminished or removed. The component (B) may be used alone or two or more components (B) may be used in combination at an arbitrary proportion.

The lower limit value of the content of the component (B) is 0.001% by mass and exemplarily 0.05% by mass with respect to the total mass of the composition for semiconductor surface treatment. On the other hand, the upper limit value of the content of the component (B) is 1% by mass and exemplarily 0.5% by mass with respect to the total mass of the composition for semiconductor surface treatment. When the content of the component (B) is in the above range, it is possible to effectively diminish or remove contaminations and to suppress corrosion of metals of the metal wiring material and the like.

### 1.3. (C) Water-soluble Polymer

The composition for semiconductor surface treatment according to the present embodiment may contain (C) a water-soluble polymer (hereinafter also referred to as “component (C)”).

By the composition for semiconductor surface treatment according to the present embodiment containing the component (C), contaminations can be effectively diminished or removed. Examples of the component (C) include polycarboxylic acid, polystyrene sulfonic acid and the like, but polycarboxylic acid may be exemplarily used, and poly(meth)acrylic acid, polymaleic acid, and copolymers thereof may also further exemplarily used. The component (C) may be used alone or two or more components (C) may be used in combination at an arbitrary proportion.

The weight average molecular weight (Mw) of the component (C) is 1,000 or more and 1,000,000 or less, or 3,000 or more and 800,000 or less. When the weight average molecular weight of the component (C) is in the above range, the component (C) is likely to be adsorbed on the surface of the metal wiring material and the like, and contaminations can be effectively diminished or removed. Moreover, in the present specification, the “weight average molecular weight (Mw)” refers to a weight average molecular weight in terms of polyethylene glycol measured by GPC (gel permeation chromatography).

When the composition for semiconductor surface treatment according to the present embodiment contains the component (C), the content of the component (C) is 0.001% to 0.1% by mass or 0.005% to 0.05% by mass with respect to the total mass of the composition for semiconductor surface treatment.

### 1.4. (D) Organic Solvent

The composition for semiconductor surface treatment according to the present embodiment may contain (D) an organic solvent (hereinafter also referred to as “component (D)”).

By the composition for semiconductor surface treatment according to the present embodiment containing the component (D), the solubility or dispersibility of the component (A) and the component (C) in the composition for semiconductor surface treatment is improved, and as a result, contaminations can be effectively diminished or removed. Examples of the component (D) include polar organic solvents such as alcohol-based solvents, ether-based solvents, ketone-based solvents, amide-based solvents, and ester-based solvents; and nonpolar organic solvents such as hydrocarbon solvents, but polar organic solvents may be exemplarily used, and alcohol-based solvents may be specifically used.

Examples of the alcohol-based solvents include methanol, ethanol, isopropanol, cyclohexanol, ethylene glycol, propylene glycol, 1,4-butanediol, and triethylene glycol, ethylene glycol monomethyl ether. In particular, isopropanol and propylene glycol may be used, and propylene glycol may be specifically used. The component (D) may be used alone or two or more components (D) may be used in combination at an arbitrary proportion.

When the composition for semiconductor surface treatment according to the present embodiment contains the component (D), the content of the component (D) is 1% to 20% by mass or 3% to 15% by mass with respect to the total mass of the composition for semiconductor surface treatment.

### 1.5. (E) Hydroxylamine

The composition for semiconductor surface treatment according to the present embodiment may contain (E) hydroxylamine (hereinafter also referred to as “component (E)”).

By the composition for semiconductor surface treatment according to the present embodiment containing the component (E), the contaminants composed of metal oxides and the like are decomposed by the high reducing action of the component (E) in some cases. As a result, the contaminants can be converted into water-soluble substances, and thus contaminations can be effectively diminished or removed.

When the composition for semiconductor surface treatment according to the present embodiment contains the component (E), the content of the component (E) is 0.001% to 5% by mass or 0.005% to 0.1% by mass with respect to the total mass of the composition for semiconductor surface treatment.

### 1.6 Other Components

The composition for semiconductor surface treatment according to the present embodiment may contain, in addition to water which is a main liquid medium, abrasive grains, a surfactant, an oxidizing agent, a pH adjusting agent, and the like, if necessary. These components may be used alone, or two or more of these components may be used concurrently.

### Water

The composition for semiconductor surface treatment according to the present embodiment contains water as a main liquid medium. Water is not particularly limited, but pure water may be used. Water may be blended as the remainder of the constituent materials of the composition for semiconductor surface treatment described above, and the content of water is not particularly limited.

### Abrasive Grains

The composition for semiconductor surface treatment according to the present embodiment may further contain abrasive grains for polishing of the metal wiring material and the like if necessary. As the abrasive grains, known materials may be used, but inorganic oxide particles and organic particles may be specifically used, for example.

Examples of the inorganic oxide particles include inorganic oxide particles such as silica, ceria, alumina, zirconia, titania, and the like. Moreover, colloidal silica may be exemplarily used from the viewpoint of suppressing generation of scratches on the metal wiring material and the like.

When the composition for semiconductor surface treatment according to the present embodiment contains abrasive grains, the content of the abrasive grains is not particularly limited to but may be 0.2% to 10% by mass or 0.3% to 5% by mass with respect to the total mass of the composition for semiconductor surface treatment.

### Surfactant

The composition for semiconductor surface treatment according to the present embodiment may contain a surfactant if necessary. Examples of the surfactant include an anionic surfactant and a nonionic surfactant.

Examples of the anionic surfactant include alkylbenzene sulfonic acids such as dodecylbenzenesulfonic acid; alkylnaphthalenesulfonic acids; alkyl sulfates such as lauryl sulfate; sulfates of polyoxyethylene alkyl ethers such as polyoxyethylene lauryl sulfate; naphthalene sulfonic acid condensate; and lignin sulfonic acid. These anionic surfactants may be used in the form of a salt.

Examples of the nonionic surfactant include polyoxyethylene alkyl ethers such as polyoxyethylene lauryl ether, polyoxyethylene cetyl ether, polyoxyethylene stearyl ether, and polyoxyethylene oleyl ether; polyoxyethylene aryl ethers such as polyoxyethylene octyl phenyl ether and polyoxyethylene nonyl phenyl ether; sorbitan fatty acid esters such as sorbitan monolaurate, sorbitan monopalmitate, and sorbitan monostearate; polyoxyethylene sorbitan fatty acid esters such as polyoxyethylene sorbitan monolaurate, polyoxyethylene sorbitan monopalmitate, and polyoxyethylene sorbitan monostearate.

These surfactants may be used alone, or two or more of these surfactants may be used concurrently. By using the surfactant, contaminants remaining on the substrate surface can be dispersed in the liquid and removed when the surface containing metal wiring material of the semiconductor substrate is treated using the composition for semiconductor surface treatment according to the present embodiment, and the desired effect of the composition for semiconductor surface treatment can be more effectively exerted.

When the composition for semiconductor surface treatment according to the present embodiment contains a surfactant, the content of the surfactant is not particularly limited to but may be 0.001% to 1% by mass or 0.001% to 0.1% by mass with respect to the total mass of the composition for semiconductor surface treatment.

### Oxidizing Agent

The composition for semiconductor surface treatment according to the present embodiment may contain an oxidizing agent if necessary. Examples of the oxidizing agent include hydrogen peroxide, organic peroxides such as peracetic acid, perbenzoic acid, and tert-butyl hydroperoxide, permanganate compounds such as potassium permanganate, dichromic acid compounds such as potassium dichromate, halogen acid compounds such as potassium iodate, nitric acid compounds such as nitric acid and iron nitrate, perhalogen acid compounds such as perchloric acid, persulfates such as ammonium persulfate, and heteropoly acids. These oxidizing agents may be used alone, or two or more of these oxidizing agents may be used concurrently.

When the composition for semiconductor surface treatment according to the present embodiment contains an oxidizing agent, the content of the oxidizing agent is not particularly limited to but may be 1% to 30% by mass or 5% to 20% by mass with respect to the total mass of the composition for semiconductor surface treatment.

### pH Adjusting Agent

The composition for semiconductor surface treatment according to the present embodiment may contain a pH adjusting agent if necessary. Examples of the pH adjusting agent include inorganic acids such as hydrochloric acid, nitric acid, sulfuric acid, and phosphoric acid; hydroxides of alkali metals such as sodium hydroxide, potassium hydroxide, rubidium hydroxide, and cesium hydroxide; and basic substances such as tetramethylammonium hydroxide (TMAH) and ammonia. Among these pH adjusting agents, hydroxides of alkali metals such as sodium hydroxide, potassium hydroxide, rubidium hydroxide, and cesium hydroxide may be specifically used and sodium hydroxide and potassium hydroxide may be further specifically used. With the pH adjusting agent as described above, the composition for semiconductor surface treatment according to the present embodiment easily adjusts the pH to 8-13 while containing the component (A) and the like, thus it is easy to control the surface states between the metal wiring material and the polishing scraps, and it is possible to effectively diminish or remove contaminations and to suppress corrosion of metals of the metal wiring material and the like. These pH adjusting agents may be used alone, or two or more of these pH adjusting agents may be used concurrently.

### 1.7. pH

The pH value of the composition for semiconductor surface treatment according to the present embodiment is 8 or more and 13 or less, 8 or more and 11 or less, or particularly 8.3 or more and 9.5 or less. When the pH value is in the above range, it is easy to control the surface states between the metal wiring material and the polishing scraps, and contaminations can be effectively diminished or removed.

The pH value of the composition for semiconductor surface treatment according to the present embodiment can be adjusted by, for example, appropriately increasing or decreasing the amounts of the component (A), the component (B), the component (C), the component (E), the pH adjusting agent, and the like that are added.

In the embodiments of the disclosure, pH refers to the hydrogen ion exponent, and the value thereof can be measured using a commercially available pH meter (for example, a desktop pH meter manufactured by Horiba, Ltd.) under the conditions of 25° C. and 1 atm.

### 2. TREATMENT METHOD OF SEMICONDUCTOR SURFACE

The treatment method of a semiconductor surface according to an embodiment of the disclosure includes a first step of dissolving or dispersing a compound represented by the following Formula (2) in water, an organic solvent, or a mixed solvent of water and an organic solvent, a second step of further dissolving or dispersing a compound represented by the following Formula (1) in the solution or dispersion after the first step, and a third step of treating a semiconductor surface using the solution or dispersion after the second step.

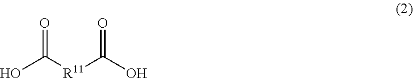

(In Formula (2), R¹¹ represents an organic group having 1 to 12 carbon atoms.)

R¹—L¹—R² (1)

(In Formula (1), R¹ represents a linear or branched alkyl group having 6 to 18 carbon atoms, R² represents an organic group having 2 or more and 5 or less nitrogen atoms, and L¹ represents a single bond or a divalent linking group.)

Hereinafter, the respective steps of the treatment method of a semiconductor surface according to the present embodiment will be described.

The first step is a step of dissolving or dispersing the component (B) described above in a liquid medium such as water. The method for dissolving or dispersing the component (B) is not particularly limited, and any method may be applied as long as the component (B) can be uniformly dissolved or dispersed. By dissolving or dispersing the component (B) having a carboxyl group in the liquid medium prior to the component (A), the hydrogen ion concentration in the liquid medium increases. Accordingly, when the component (A) is dissolved or dispersed in the second step described later, the amino group of the component (A) is protonated to an ammonium cation, and an environment in which polarity is easily obtained is prepared, and thus the component (A) is easily dissolved or dispersed in the liquid medium.

The second step is a step of dissolving or dispersing the component (A) in the solution or dispersion obtained in the first step to obtain a composition for semiconductor surface treatment. At this time, the component (C), the component (D), the component (E), and the other components may be added if necessary. In addition, in the second step, a pH adjusting agent may be used to adjust the pH value of the solution or dispersion obtained in the first step to a range of 8 or more and 13 or less.

The third step is a step of treating the semiconductor surface using the composition for semiconductor surface treatment obtained in the second step. As described above, the composition for semiconductor surface treatment containing the component (A) and the component (B) can effectively diminish or remove contaminations of the metal wiring material and the like and suppress corrosion of metals of the metal wiring material and the like. For this reason, the treatment method according to the present embodiment is useful when treating a wiring board present on a semiconductor surface.

The treatment method is not particularly limited and is carried out by a method in which the composition for semiconductor surface treatment described above is brought into direct contact with the wiring board. Examples of the method for bringing the composition for semiconductor surface treatment into direct contact with the wiring board include a dipping method in which a cleaning tank is filled with the composition for semiconductor surface treatment and the wiring board is immersed in the composition; a spinning method in which the wiring board is rotated at a high speed while the composition for semiconductor surface treatment flows from the nozzle onto the wiring board; and a spray method in which the wiring board is cleaned by spraying the composition for semiconductor surface treatment onto the wiring board. In addition, examples of an apparatus for carrying out the above method include a batch type cleaning apparatus that simultaneously cleans a plurality of wiring boards housed in a cassette and a single wafer cleaning apparatus that mounts a single wiring board on a holder and cleans the wiring board.

In the treatment method according to the present embodiment, the temperature of the composition for semiconductor surface treatment is usually set to room temperature, but the temperature may be raised in the range in which the performance is not impaired and can be raised to, for example, about 40° C. to 70° C.

In addition, it is also possible to concurrently use a cleaning method using physical force in addition to the above-described method in which the composition for semiconductor surface treatment is brought into direct contact with the wiring board. Accordingly, the removal property of contaminations by the particles attached to the wiring board is improved and the cleaning time can be shortened. Examples of the cleaning method using physical force include scrub cleaning using a cleaning brush and ultrasonic cleaning.

Furthermore, cleaning using ultrapure water or an alcohol-based solvent such as isopropanol may be performed before and/or after the treatment by the treatment method according to the present embodiment.

### 3. EXAMPLES

Hereinafter, the disclosure will be described with reference to examples, but the disclosure is not limited to these examples. Moreover, “parts” and “%” in examples are based on mass unless otherwise stated.

### 3.1. Preparation of Composition for Semiconductor Surface Treatment

Ion-exchanged water and the component (D) presented in Table 1 or Table 2 were input into a polyethylene container and then the component (B) presented in Table 1 or Table 2 was input. Thereafter, the components described in the column of “component (A) and others” in Table 1 or Table 2 were input into the polyethylene container, then the remaining components were charged, and stirring was performed for 15 minutes. Thereafter, the pH adjusting agent described in Table 1 or Table 2 was added to the resultant mixture so that the pH of the mixture became the value described in Table 1 or Table 2, and stirring was further performed for 15 minutes, thereby obtaining the compositions for semiconductor surface treatment of Examples 1 to 19 and Comparative Examples 1 to 5.

### 3.2 Evaluation Test

### 3.2.1. Calculation of Etching Rate (ER)

An 8-inch silicon wafer on which a tungsten (W) film was formed by sputtering (8-inch silicon substrate with thermal oxide film on which a tungsten film having a thickness of 2,000 A was laminated) was cut to 1 cm×3 cm to obtain a metal wafer test piece. The film thickness of this test piece was previously measured using a metal film thickness meter “RG-5” manufactured by NPS Corporation. Next, 100 mL of the composition for semiconductor surface treatment of any of Examples 1 to 19 and Comparative Examples 1 to 5 was placed in a polyethylene container and kept at 60° C. The metal wafer test piece on which a tungsten film was formed was immersed in the composition for semiconductor surface treatment for 60 minutes. Thereafter, the metal wafer test piece was washed with running water for 10 seconds and dried. The film thickness of the metal wafer test piece after the immersion treatment was measured again, and the etching rate (ER, unit: Å/min.) was calculated by dividing the quantity of film thickness decreased by the immersion time of 60 minutes. The results are collectively presented in Table 1 or Table 2.

### 3.2.2 Evaluation on Corrosion Observation

An 8-inch silicon wafer on which a tungsten (W) film was formed by sputtering (8-inch silicon substrate with thermal oxide film on which a tungsten film having a thickness of 2,000 A was laminated) was cut to 1 cm×1 cm to obtain metal wafer test pieces. The surfaces of these test pieces were observed under a scanning electron microscope at a magnification of 50000-fold. 50 mL of the composition for semiconductor surface treatment of any of Examples 1 to 19 and Comparative Examples 1 to 5 was placed in a polyethylene container and kept at 25° C. The test piece (1 cm×1 cm) was immersed in the composition for 60 minutes, washed with running water for 10 seconds and dried. Thereafter, the corrosion of the surface was observed again under the scanning electron microscope at a magnification of 50000-fold and evaluated according to the following criteria. The results are presented in Table 1 or Table 2.

### Evaluation Criteria

A: Change in surface shape due to corrosion was not observed as compared with surface shape before immersion.

B: There were both corroded spots and uncorroded spots as compared with surface before immersion.

C: Entire surface was corroded as compared to surface before immersion.

### 3.2.3 Defect Evaluation

The cleaning treatment after chemical mechanical polishing was performed using the composition for semiconductor surface treatment of any of Examples 1 to 19 and Comparative Examples 1 to 5, and the defect evaluation of this treatment was performed. The specific procedure is as follows.

First, colloidal silica water dispersion PL-3 (manufactured by Fuso Chemical Co., Ltd.) was input into a polyethylene container so as to be in an amount corresponding to 1% by mass in terms of silica, and ion-exchanged water and maleic acid serving as a pH adjusting agent were added into the polyethylene container so that the total of all constituents was 100% by mass to adjust the pH to 3. Furthermore, 35% by mass hydrogen peroxide serving as an oxidizing agent was added to the mixture so as to be at 1% by mass in terms of hydrogen peroxide, and stirring was performed for 15 minutes to obtain a composition for chemical mechanical polishing. An 8-inch silicon substrate with thermal oxide film on which a tungsten film having a thickness of 2,000 Å was laminated or an 8-inch silicon substrate on which a PETEOS film having a thickness of 10,000 Å was laminated was cut to 3 cm×3 cm to obtain a wafer test piece. A chemical mechanical polishing treatment was performed for 1 minute using this wafer test piece as an object to be polished under the following polishing conditions.

### Polishing Conditions

Polishing apparatus: “LM-15C” manufactured by Lapmaster SFT Corporation
Polishing pad: “IC1000/K-Groove” manufactured by RODEL NITTA
Number of revolutions of polishing plate: 90 rpm
Number of revolutions of head: 90 rpm
Head pressing pressure: 3 psi
Supply rate of composition for chemical mechanical polishing: 100 mL/min

Subsequently, a water washing treatment on the polishing pad was performed for 10 seconds under washing conditions in which the supply rate of ion-exchanged water was 500 mL/min. Five spots in each metal wafer test piece which had been subjected to the chemical mechanical polishing treatment by the above method were observed in a frame size of 10 μm using Dimension FastScan, a scanning atomic force microscope (AFM) manufactured by Bruker Corporation. Only metal wafer test pieces which had been confirmed to have a flat surface with an average value of arithmetic average roughness at five spots of 0.1 nm or less were sorted out and used in the next defect evaluation.

The temperature of 50 mL of the composition for semiconductor surface treatment of any of Examples 1 to 19 and Comparative Examples 1 to 5 was kept at 25° C., and the test pieces sorted out above were immersed in the composition for 15 minutes, washed with running water for 10 seconds and dried. Thereafter, five spots per each test piece were observed in a frame size of 10 μm using AFM. Five images obtained were analyzed using image analysis software, and the sum of attachments having a height of 2.0 nm or more was taken as the number of defects. The evaluation criteria are as follows. The number of defects and the evaluation results are presented in Table 1 or Table 2.

### Evaluation Criteria

A: Number of defects is less than 100 defects

B: Number of defects is 100 or more and less than 500

C: Number of defects is 500 or more

### 3.3 Evaluation Results

The composition and evaluation results of the compositions for semiconductor surface treatment are presented in the following Tables 1 and 2.

TABLE 1

| | | Example | Example | Example | Example | Example | Example | Example | Example | Example | Example | Exam- | Exam- |
|---|---|---|---|---|---|---|---|---|---|---|---|---|---|
| | | 1 | 2 | 3 | 4 | 5 | 6 | 7 | 8 | 9 | 10 | ple 11 | ple 12 |
| Component | Dodecyl | 0.01 | 0.01 | | | | | | 0.05 | 0.001 | 0.01 | 0.01 | 0.01 |
| (A) and | dipropylene | | | | | | | | | | | | |
| others | triamine | | | | | | | | | | | | |
| | Beef tallow | | | 0.01 | | | | | | | | | |
| | dipropylene | | | | | | | | | | | | |
| | triamine | | | | | | | | | | | | |
| | Dodecyl- | | | | 0.01 | | | | | | | | |
| | aminoethyl- | | | | | | | | | | | | |
| | aminoethyl- | | | | | | | | | | | | |
| | glycine | | | | | | | | | | | | |
| | N-coconut | | | | | 0.01 | | | | | | | |
| | alkyl-1,3- | | | | | | | | | | | | |
| | diamino- | | | | | | | | | | | | |
| | propane | | | | | | | | | | | | |
| | N-oleyl-1,3- | | | | | | 0.01 | | | | | | |
| | diamino- | | | | | | | | | | | | |
| | propane | | | | | | | | | | | | |
| | Amidopropyl | | | | | | | 0.01 | | | | | |
| | betaine | | | | | | | | | | | | |
| | laurate | | | | | | | | | | | | |
| | Monosodium | | | | | | | | | | | | |
| | laurylamino- | | | | | | | | | | | | |
| | diacetate | | | | | | | | | | | | |
| | Polyethylene- | | | | | | | | | | | | |
| | imine (Mw = | | | | | | | | | | | | |
| | 600) | | | | | | | | | | | | |
| | Monoethanol- | | | | | | | | | | | | |
| | amine | | | | | | | | | | | | |
| Component | Citric acid | 0.01 | 0.01 | 0.01 | 0.01 | 0.01 | 0.01 | 0.01 | 0.01 | 0.01 | | | 0.01 |
| (B) | Malonic acid | | | | | | | | | | 0.01 | | |
| | EDTA | | | | | | | | | | | 0.01 | |
| Component | Polyacrylic | | | | | | | | | | | | 0.01 |
| (C) | acid (Mw = | | | | | | | | | | | | |
| | 50,000) | | | | | | | | | | | | |
| | Polystyrene | | | | | | | | | | | | |
| | sulfonic acid | | | | | | | | | | | | |
| | (Mw = | | | | | | | | | | | | |
| | 75,000) | | | | | | | | | | | | |
| Component | Propylene | 5 | 5 | 5 | 5 | 5 | 5 | 5 | 5 | 5 | 5 | 5 | |
| (D) | glycol | | | | | | | | | | | | |
| | Isopropanol | | | | | | | | | | | | |
| Component | Hydroxyl- | | | | | | | | | | | | |
| (E) | amine | | | | | | | | | | | | |

| | | | | | | | | | | | | |
|---|---|---|---|---|---|---|---|---|---|---|---|---|
| pH adjusting agent | KOH | KOH | KOH | KOH | KOH | KOH | KOH | KOH | KOH | KOH | KOH | KOH |
| pH (25° C.) | 8.4 | 8.4 | 8.4 | 8.4 | 8.4 | 8.4 | 8.4 | 8.4 | 8.4 | 8.4 | 8.4 | 8.4 |

Evaluation results

| | | | | | | | | | | | | | |
|---|---|---|---|---|---|---|---|---|---|---|---|---|---|
| W | ER [Å/min.] | 0.2 | 0.2 | 0.5 | 0.4 | 1.4 | 1.2 | 1.6 | 0.1 | 1.3 | 0.3 | 0.4 | 0.9 |
| | Corrosion | A | A | A | A | B | B | B | A | B | A | A | A |
| | evaluation | | | | | | | | | | | | |
| | (SEM) | | | | | | | | | | | | |
| | Defect | 75 | 34 | 27 | 49 | 60 | 93 | 29 | 155 | 32 | 84 | 223 | 11 |
| | evaluation | | | | | | | | | | | | |
| | (AFM) | A | A | A | A | A | A | A | B | A | A | B | A |
| PETEOS | Defect | 77 | 14 | 81 | 66 | 26 | 41 | 17 | 86 | 11 | 69 | 65 | 19 |
| | evaluation | | | | | | | | | | | | |
| | (AFM) | A | A | A | A | A | A | A | A | A | A | A | A |

TABLE 2

| | | | | | | | | | Com- | Com- | Com- | Com- | Com- |
|---|---|---|---|---|---|---|---|---|---|---|---|---|---|
| | | | | | | | | | parative | parative | parative | parative | parative |
| | | Example | Example | Exam- | Exam- | Exam | Exam- | Exam- | Example | Example | Example | Example | Example |
| | | 13 | 14 | ple 15 | ple16 | ple 17 | ple 18 | ple 19 | 1 | 2 | 3 | 4 | 5 |
| Compon- | Dodecyl | 0.01 | 0.01 | 0.01 | 0.01 | 0.01 | 0.01 | 0.01 | | | | | |
| ent (A) | dipropylene | | | | | | | | | | | | |
| and others | triamine | | | | | | | | | | | | |
| | Beef tallow | | | | | | | | | | | | |
| | dipropylene | | | | | | | | | | | | |
| | triamine | | | | | | | | | | | | |
| | Dodecyl- | | | | | | | | | | | | |
| | aminoethyl- | | | | | | | | | | | | |
| | aminoethyl- | | | | | | | | | | | | |
| | glycine | | | | | | | | | | | | |
| | N-coconut | | | | | | | | | | | | |
| | alkyl-1,3- | | | | | | | | | | | | |
| | diamino- | | | | | | | | | | | | |
| | propane | | | | | | | | | | | | |
| | N-oleyl-1,3- | | | | | | | | | | | | |
| | diamino- | | | | | | | | | | | | |
| | propane | | | | | | | | | | | | |
| | Amido- | | | | | | | | | | 0.01 | | |
| | propyl | | | | | | | | | | | | |
| | betaine | | | | | | | | | | | | |
| | laurate | | | | | | | | | | | | |
| | Monosodium | | | | | | | 0.01 | | | | | |
| | laurylamino- | | | | | | | | | | | | |
| | diacetate | | | | | | | | | | | | |
| | Polyethylene- | | | | | | | | 0.01 | | | 0.01 | |
| | imine (Mw = | | | | | | | | | | | | |
| | 600) | | | | | | | | | | | | |
| | Monoethano- | | | | | | | | | 0.01 | | | |
| | lamine | | | | | | | | | | | | |
| Compon- | Citric acid | 0.01 | 0.01 | 0.01 | 0.01 | 0.01 | 0.01 | 0.01 | 0.01 | 0.01 | 0.01 | | 0.01 |
| ent (B) | Malonic acid | | | | | | | | | | | | |
| | EDTA | | | | | | | | | | | | |
| Compon- | Polyacrylic | | | | | | | 0.01 | | | | | |
| ent (C) | acid (Mw = | | | | | | | | | | | | |
| | 50,000) | | | | | | | | | | | | |
| | Polystyrene | 0.01 | | | | | | | | | | | |
| | sulfonic acid | | | | | | | | | | | | |
| | (Mw = | | | | | | | | | | | | |
| | 75,000) | | | | | | | | | | | | |
| Compon- | Propylene | 5 | | 5 | 5 | 5 | 5 | 5 | 5 | 5 | 5 | 5 | 5 |
| ent (D) | glycol | | | | | | | | | | | | |
| | Isopropanol | | 5 | | | | | | | | | | |
| Compon- | Hydroxyl- | | | 0.01 | | | | 0.01 | | | | | |
| ent (E) | amine | | | | | | | | | | | | |

| | | | | | | | | | | | | |
|---|---|---|---|---|---|---|---|---|---|---|---|---|
| pH adjusting agent | KOH | KOH | KOH | KOH | KOH | HNO₃ | KOH | KOH | KOH | KOH | KOH | KOH |
| pH (25° C.) | 8.4 | 8.4 | 8.4 | 8.0 | 10.0 | 3.0 | 8.4 | 8.4 | 8.4 | 8.4 | 8.4 | 10.0 |

Evaluation results

| | | | | | | | | | | | | | |
|---|---|---|---|---|---|---|---|---|---|---|---|---|---|
| W | ER [Å/min.] | 1.5 | 0.7 | 0.8 | 0.1 | 0.6 | 0.1 | 0.1 | 22.8 | 3.7 | 33.1 | 0.9 | 18.8 |
| | Corrosion | A | A | A | A | A | A | A | C | B | C | B | C |
| | evaluation | | | | | | | | | | | | |
| | (SEM) | | | | | | | | | | | | |
| | Defect | 53 | 176 | 31 | 76 | 189 | 288 | 17 | 82 | 532 | 191 | 798 | 294 |
| | evaluation | A | B | A | A | B | B | A | A | C | B | C | B |
| | (AFM) | | | | | | | | | | | | |
| PETEOS | Defect | 21 | 74 | 35 | 131 | 80 | 112 | 26 | 132 | 115 | 16 | 566 | 110 |
| | evaluation | A | A | A | B | A | A | A | B | B | A | C | B |
| | (AFM) | | | | | | | | | | | | |

In Tables 1 and 2 above, the numerical value of each component represents parts by mass. In each example and each comparative example, the total amount of the respective components is 100 parts by mass, and the remainder is ion-exchanged water. Moreover, the following components in Tables 1 and 2 are supplemented.

### Component (A) and Others

Dodecyl dipropylene triamine: trade name “Triameen Y12D” manufactured by Akzo Nobel N.V.
Beef tallow dipropylene triamine: trade name “Triameen T” manufactured by Akzo Nobel N.V.
Dodecylaminoethylaminoethylglycine: trade name “LEBON S” manufactured by Sanyo Chemical Industries, Ltd.
N-coconut alkyl-1,3-diaminopropane: trade name “Duomeen CD” manufactured by Akzo Nobel N.V.
N-oleyl-1,3-diaminopropane: trade name “Duomeen 0” manufactured by Akzo Nobel N.V.
Amidopropyl betaine laurate: trade name “AMPHITOL 20AB” manufactured by Kao Corporation
Monosodium laurylaminodiacetate: trade name “Nissan Anon LA” manufactured by NOF Corporation
Polyethyleneimine: trade name “Polyethyleneimine 600”, Mw =600 manufactured by JUNSEI CHEMICAL CO., LTD.
Monoethanolamine: trade name “2-Sminoethanol” manufactured by Hayashi Pure Chemical Ind., Ltd.

### Component (B)

Citric acid: trade name “Citric Acid (crystal)” manufactured by Hayashi Pure Chemical Ind., Ltd.
Malonic acid: trade name “Malonic Acid” manufactured by JUZEN Co., Ltd.
EDTA: trade name “CHELEST 3A” manufactured by CHELEST CORPORATION

### Component (C)

Polyacrylic acid: trade name “AC-10L”, Mw=50,000 manufactured by TOAGOSEI CO., LTD.
Polystyrene sulfonic acid: trade name “VERSA-TL72”, Mw=75,000 manufactured by Akzo Nobel N.V.

### Component (D)

Propylene glycol: trade name “Industrial Propylene Glycol” manufactured by ADEKA CORPORATION
Isopropanol: trade name “Isopropyl Alcohol” manufactured by Sankyo Chemical Co., LTD.

### Component (E)

Hydroxylamine: trade name “Hydroxylamine (50% in Water)” manufactured by Tokyo Chemical Industry Co., Ltd.

As is apparent from Tables 1 and 2 above, when the compositions for semiconductor surface treatment according to Examples 1 to 19 were used, the corrosion state of the semiconductor surface was suppressed, the number of defects was small, and favorable cleaning performance of the semiconductor surface can be realized in all the cases.

According to the composition for semiconductor surface treatment of the embodiments of the disclosure, it is possible to effectively diminish or remove contaminations from the semiconductor surface and to suppress damage to a metal wiring material and the like when the composition is used in treatments such as polishing and cleaning. The composition for semiconductor surface treatment of the embodiments of the disclosure is particularly effective when the metal wiring material is tungsten or cobalt.

The disclosure is not limited to the above-described embodiments, and various modifications can be made. For example, the disclosure includes configurations (for example, configurations with the same functions, methods, and results, or configurations with the same objective and effect) that is substantially the same as the configuration described in the embodiment. In addition, the disclosure includes configurations in which a non-essential part of the configuration described in the embodiment is replaced. Moreover, the disclosure includes configurations that exert the same effect as the configuration described in the embodiment or configurations that can achieve the same objective. In addition, the disclosure includes configurations in which a known technology is added to the configuration described in the embodiment.

What is claimed is:

1. A composition for semiconductor surface treatment, comprising:
(A) a compound represented by the following Formula (1); and
(B) a compound represented by the following Formula (2);
R¹—L¹—R² (1)
in Formula (1), R¹ represents a linear or branched alkyl group having 6 to 18 carbon atoms, R² represents an organic group having 2 or more and 5 or less nitrogen atoms, and L¹ represents a single bond or a divalent linking group; 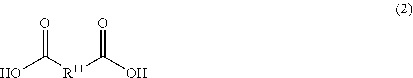
in Formula (2), R¹¹ represents an organic group having 1 to 12 carbon atoms.

2. The composition for semiconductor surface treatment according to claim 1, wherein R² in the compound represented by Formula (1) is a group represented by the following Formula (3); 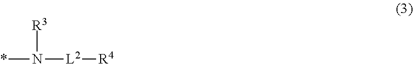
in Formula (3), R³ represents a hydrogen atom or an aminoalkyl group, R⁴ represents an organic group having 1 to 6 carbon atoms, L² represents a divalent linking group, and * represents a binding site with L¹.

3. The composition for semiconductor surface treatment according to claim 2, wherein the group represented by Formula (3) is a group represented by the following Formula (4) or a group represented by the following Formula (5); 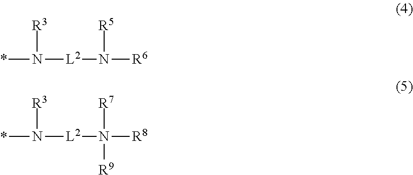
in Formula (4) and Formula (5), R³ represents a hydrogen atom or an aminoalkyl group; R⁵ and R⁶ in Formula (4) each independently represent a hydrogen atom, an aminoalkyl group, or a carboxyalkyl group; R⁷, R⁸, and R⁹ in Formula (5) each independently represent a linear or branched alkyl group having 1 to 5 carbon atoms or a group represented by the following Formula (6), wherein at least one of R⁷, R⁸, and R⁹ is a group represented by the following Formula (6); L² represents a divalent linking group; and * represents a binding site with L¹;
*—R¹⁰—COO⁻ 6)
in Formula (6), R¹⁰ represents an alkylene group having 1 to 3 carbon atoms, and * represents a binding site with N⁺.

4. The composition for semiconductor surface treatment according to claim 2, wherein R³ in Formula (3) is an aminoalkyl group having 1 to 6 carbon atoms.

5. The composition for semiconductor surface treatment according to claim 2, wherein L² in Formula (3) is a linking group containing at least one selected from the group consisting of alkylene groups having 1 to 5 carbon atoms and an amino group.

6. The composition for semiconductor surface treatment according to claim 2, wherein L² in Formula (3) is a linking group containing an alkylene group having 1 to 5 carbon atoms and an amino group.

7. The composition for semiconductor surface treatment according to claim 1, wherein the compound represented by Formula (1) is a compound having 3 or more and 5 or less nitrogen atoms.

8. The composition for semiconductor surface treatment according to claim 1, wherein the compound represented by Formula (2) is at least one compound selected from the group consisting of citric acid, malonic acid, maleic acid, tartaric acid, malic acid, and succinic acid.

9. The composition for semiconductor surface treatment according to claim 1, wherein the pH is 8 or more and 13 or less.

10. The composition for semiconductor surface treatment according to claim 1, further comprising (C) a water-soluble polymer.

11. The composition for semiconductor surface treatment according to claim 1, further comprising (D) an organic solvent.

12. The composition for semiconductor surface treatment according to claim 1, further comprising (E) hydroxylamine.

13. The composition for semiconductor surface treatment according to claim 1, which is used for a wiring board.

14. A treatment method of a semiconductor surface, comprising:
a first step of dissolving or dispersing a compound represented by the following Formula (2) in water, an organic solvent, or a mixed solvent of water and the organic solvent;
a second step of further dissolving or dispersing a compound represented by the following Formula (1) in the solution or dispersion after the first step; and
a third step of treating a semiconductor surface using the solution or dispersion after the second step; 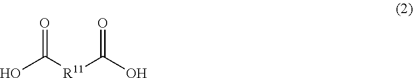
in Formula (2), R¹¹ represents an organic group having 1 to 12 carbon atoms;
R¹—L¹—R² (1)
in Formula (1), R¹ represents a linear or branched alkyl group having 6 to 18 carbon atoms, R² represents an organic group having 2 or more and 5 or less nitrogen atoms, and L¹ represents a single bond or a divalent linking group.
